(19) United States
(12) Patent Application Publication
(10) Pub. No.: US 2015/0179716 A1
(43) Pub. Date: Jun. 25, 2015

(54) SURFACE LIGHT-EMITTING DEVICE

(71) Applicant: Kazuo Kuroda, Yokohama-shi (JP)

(72) Inventor: Kazuo Kuroda, Yokohama-shi (JP)

(73) Assignee: Pioneer Corporation, Kawasaki-shi, Kanagawa (JP)

(21) Appl. No.: 14/413,657

(22) PCT Filed: Jul. 19, 2012
(86) PCT No.: PCT/JP2012/068344

§ 371 Date: Jan. 8, 2015

(51) Int. Cl. H01L 27/32; H05B 33/08

(52) U.S. Cl. CPC H01L 27/3218; H01L 27/3213; H05B 33/0896

(57) ABSTRACT

A surface light-emitting device having a light-emitting surface including at least one single-color light-emitting panel and at least one multi-color light-emitting panel disposed alongside the single-color light-emitting panel.

### TECHNICAL FIELD

The present invention relates to a surface light-emitting device that emits light from the surface.

### BACKGROUND ART

Light-emitting devices having organic EL panels as light sources have been proposed. Light-emitting devices having organic EL panels have the characteristic of no restriction on shape for surface light emission. Accordingly, further development of such light-emitting devices can be expected for future practical application because such characteristic is not obtained from other light-emitting devices such as LED (light-emitting diode) light-emitting devices.

In general, organic EL panels as light sources of surface light-emitting devices have an anode made of a transparent conductive film, such as ITO, and formed on a transparent substrate; a cathode made of a metal, such as Al; and an organic light-emitting functional layer with an organic multilayer structure interposed between the anode and the cathode (Patent Document 1). The organic light-emitting functional layer, which is made from organic materials, has a lamination including, in sequence from the anode side, for example, a hole injection/transport layer, a light-emitting layer, an electron transport layer, and an electron injection layer. The lamination can be formed using, for example, a vacuum deposition method or an ink jet method. Such organic EL panels have an organic light emitting functional layer in a stripe manner so as to obtain high luminance with the entire light-emitting surface.

### CITATION LIST

### Patent Documents

Patent Document 1: Japanese Patent No. 4567092

### SUMMARY OF THE INVENTION

### Problem to be Solved by the Invention

Such surface light-emitting devices usually include those of single-color light emission and those of multi-color (or full-color) light emission. Light-emitting devices of single-color light emission only allow adjustment of the luminance of single-color light emission for each panel, and thus have a disadvantage of difficulty in complex expression due to the lack of color adjustment. On the other hand, surface light-emitting devices of multi-color light emission have a disadvantage of requiring drive circuits that drive the respective organic EL elements of RGB (red, green, and blue) separately. In addition, the panels including a plurality of RGB organic EL elements for complex expression have disadvantages of a complex drive control system and high cost.

The above disadvantages are mentioned as examples of the problems that the present invention is to solve. An object of the present invention is to provide a surface light-emitting device that enables multi-color pattern light emission by including a drive control system with a simpler configuration than conventional surface light-emitting devices of multi-color light emission, and also enables uniform light emission on the basis of previously obtained data in order to adjust the luminance and chromaticity among a plurality types of panels during single-color light emission.

### Means to Solve the Problem

A surface light-emitting device of the present invention according to claim 1 comprises a light-emitting surface including a single-color area and a multi-color area disposed alongside of the single-color area, wherein the single-color area is formed by a plurality of single-color light-emitting panels and the multi-color area is formed by a plurality of multi-color light-emitting panels, and the amount of light emission from each multi-color panel is controlled with the correlation data between the single-color panels and the multi-color panels, which are stored in a memory in advance, in the achievement of color emission and single-color emission such as white, thereby keeping uniform the light emission conditions, such as luminance and chromaticity, of the single-color panels and the multi-color panels.

### BRIEF DESCRIPTION OF DRAWINGS

FIG. 1 is a front view of a light-emitting surface of an organic EL panel block in a surface light-emitting device according to an embodiment of the present invention.

FIG. 2 is a cross-sectional view of a white light-emitting panel in the organic EL panel block of FIG. 1.

FIG. 3 is a cross-sectional view of a full-color light-emitting panel in the organic EL panel block of FIG. 1.

FIG. 4 is a block diagram illustrating a drive control system that drives the organic EL panel block of FIG. 1.

FIG. 5 is a front view of an operation unit in the drive control system of FIG. 4.

FIG. 6 is a diagram illustrating the area ratio of the luminance level of white light emission of the white light-emitting panel to the luminance levels of RGB of the full-color light-emitting panel while these panels are driven.

FIG. 7 is a diagram illustrating the use mode of the surface light-emitting device of FIG. 1.

FIG. 8 is a diagram illustrating the use mode of the surface light-emitting device of FIG. 1.

FIG. 9 is a diagram illustrating an exemplary evacuation directional sign in the non-power failure mode of the surface light-emitting device of FIG. 1.

FIG. 10 is a diagram illustrating an exemplary evacuation directional sign in the power failure mode of the surface light-emitting device of FIG. 1.

FIG. 11 is a front view of a light-emitting surface of an organic EL panel block in a surface light-emitting device according to another embodiment of the present invention.

FIG. 12 is a front view of a light-emitting surface of an organic EL panel block in a surface light-emitting device according to another embodiment of the present invention.

FIG. 13 is a front view of a light-emitting surface of an organic EL panel block in a surface light-emitting device according to another embodiment of the present invention.

FIG. 14 is a front view of a light-emitting surface of an organic EL panel block in a surface light-emitting device according to another embodiment of the present invention.

### EMBODIMENTS

Hereinafter, the embodiments of the present invention will be described with reference to the drawings.

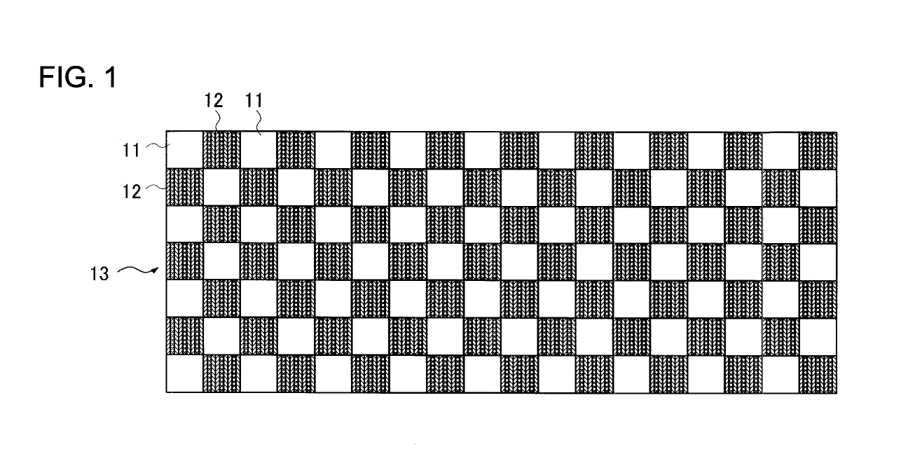

The surface light-emitting device according to an embodiment illustrated in FIG. 1 has an organic EL panel block 13 including a plurality of white light-emitting panels 11 and a plurality of full-color light-emitting panels 12. The plurality of white light-emitting panels 11 form white areas (single-color areas) of the light-emitting surface of the surface light-emitting device, whereas the plurality of full-color light-emitting panels 12 form multi-color areas disposed alongside the white areas of the light-emitting surface. Each of the white light-emitting panels 11 and the full-color light-emitting panels 12 is a tile-like unit panel and is, for example, a square of 15 cm×15 cm in size. The four sides of the white light-emitting panel 11 are in contact with full-color light-emitting panels 12, respectively, while the four sides of the full-color light-emitting panel 12 are in contact with four white light-emitting panels 11, respectively. Such arrangement of the white light-emitting panels 11 and the full-color light-emitting panels 12 shows a checkered pattern (check pattern) as a predetermined pattern in the light-emitting surface. The white light-emitting panels 11 and the full-color light-emitting panels 12 are not limited to square and may be rectangle.

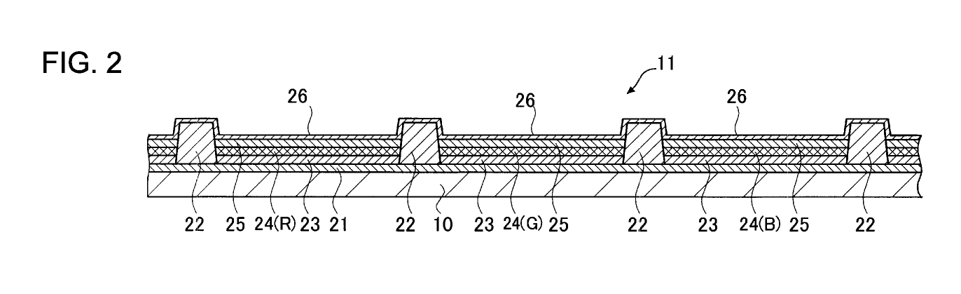

In the white light-emitting panel 11, as illustrated in FIG. 2, a transparent electrode 21 is formed as an anode on a glass substrate 10. The transparent electrode 21 is formed by, for example, sputtering and is made of an ITO film. On the transparent electrode 21, a plurality of long banks 22 are arranged at regular intervals. The banks 22 are made of an organic insulating material. The organic insulating material is applied to the transparent electrode 21 by a spin coating method or a printing method. After the material is dried, the banks 22 are formed by patterning with photolithographic technique. The banks 22 have a trapezoidal cross section in the direction perpendicular to the longitudinal direction and have a forward tapered side on the transparent electrode 21.

The light-emitting regions described above are positioned between adjacent banks 22. In each light-emitting region, a hole injection layer 23, a light-emitting layer 24, and an electron injection layer 25 are formed in this order as an organic light-emitting structure layer. The hole injection layer 23, the light-emitting layer 24, and the electron injection layer 25 are each formed by applying inks including their respective materials using a coating method such as an ink-jet method, followed by drying after the application. Regarding the light-emitting layer 24, light-emitting layers with different colors are disposed in adjacent light-emitting regions; and red light-emitting layers 24(R), green light-emitting layers 24(G), and blue light-emitting layers 24(B) are repeatedly disposed in this order in the arrangement direction of the banks 22. The organic light-emitting structure layer is not limited to the above configuration, and may include a hole transport layer between the hole injection layer 23 and the light-emitting layer 24 and/or may include an electron transport layer between the light-emitting layer 24 and the electron injection layer 25.

On the electron injection layer 25, for example, an Al film is formed by, for example, vacuum deposition, whereby a metal electrode 26 is formed. The metal electrode 26 functions as a cathode. The metal electrode 26 is provided through the entire light-emitting regions. The metal electrode 26 is sealed with a sealing material such as resin, although not illustrated in the figure.

Although white is constructed with the stripe configuration of RGB, white light may be emitted with a tandem structure or laminated structure.

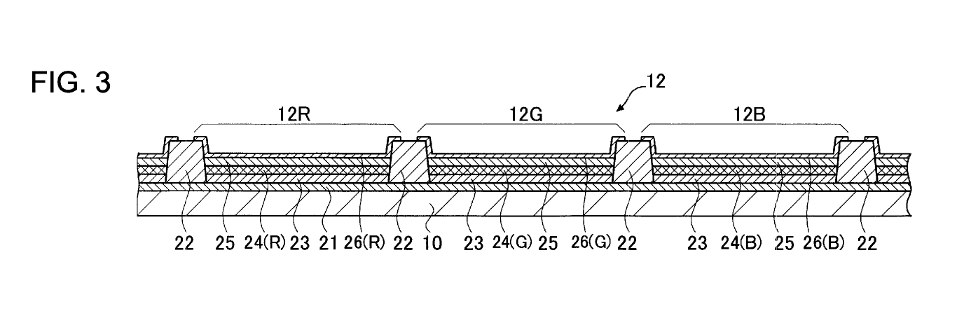

The full-color light-emitting panel 12, as illustrated in FIG. 3, has the same structure as the white light-emitting panel 11 except that metal electrodes 26 are provided as 26(R), 26(G), and 26(B) for each RGB by pattering with photolithographic technique. The RGB as used herein corresponds to a red light-emitting element 12R, a green light-emitting element 12G, and a blue light-emitting element 12B. Specifically, the red light-emitting element 12R is a portion including the transparent electrode 21, the hole injection layer 23, the red light-emitting layer 24(R), the electron injection layer 25, and the metal electrode 26(R). The green light-emitting element 12G is a portion including the transparent electrode 21, the hole injection layer 23, the green light-emitting layer 24(G), the electron injection layer 25, and the metal electrode 26(G). The blue light-emitting element 12G is a portion including the transparent electrode 21, the hole injection layer 23, the blue light-emitting layer 24(B), the electron injection layer 25, and the metal electrode 26(B).

When each light-emitting layer 24 of the white light-emitting panels 11 and the full-color light-emitting panels 12 emits light, the light is directed to the outside through the hole injection layer 23, the transparent electrode 21, and then the glass substrate 10. The light generated in the light-emitting layer 24 is reflected on the metal electrode 26 through the electron injection layer 25, and the reflected light is directed to the outside through the electron injection layer 25, the light-emitting layer 24, the hole injection layer 23, the transparent electrode 21, and then the glass substrate 10.

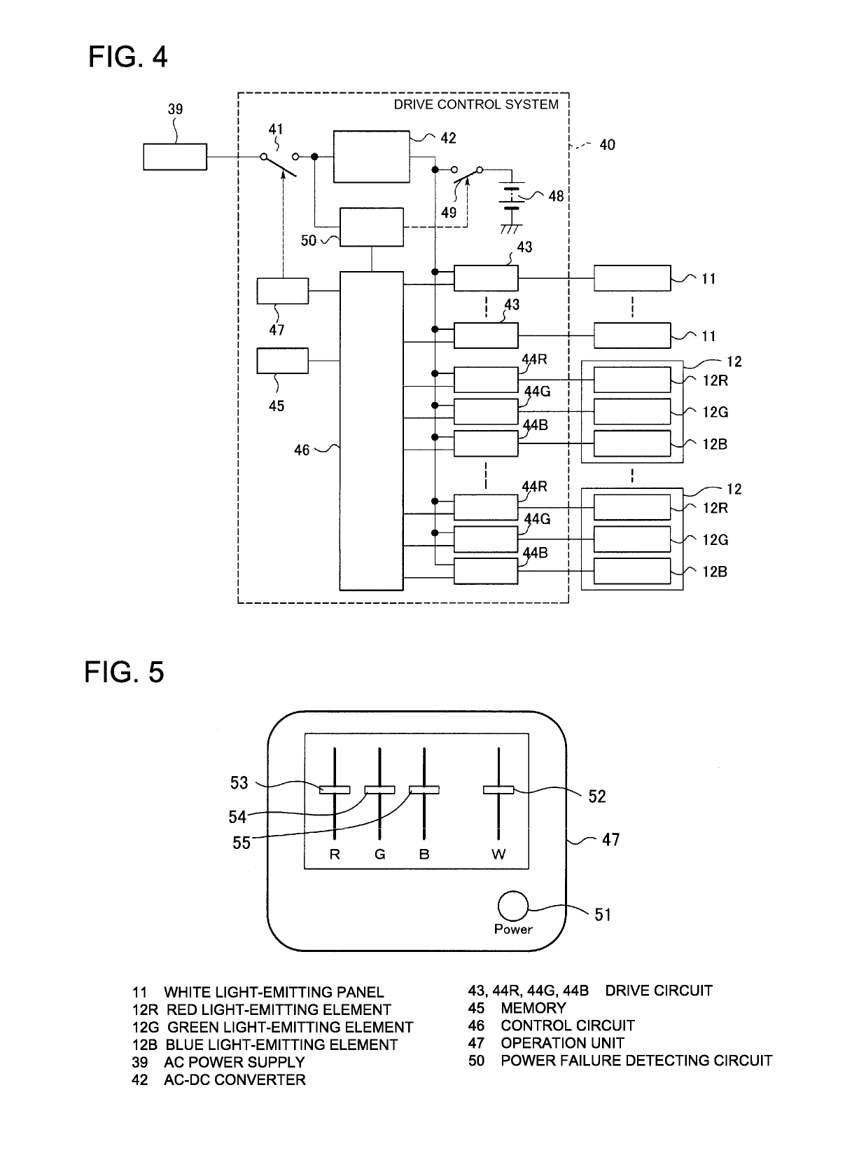

A drive control system 40 that drives the white light-emitting panels 11 and the full-color light-emitting panels 12 in the organic EL panel block 13 has the configuration as illustrated in FIG. 4. In this drive control system 40, the output voltage from an AC power supply 39 is applied to an AC-DC converter 42 through a power switch 41. The AC-DC converter 42 converts an output voltage from the AC power supply 39 into a direct-current voltage while the power switch 41 is on. The AC power supply 39 is, for example, a commercial power supply. The output of the AC-DC converter 42 is connected with drive circuits 43 (first drive circuits) for the white light-emitting panels 11 and drive circuits 44R, 44G, and 44B (second drive circuits) for the full-color light-emitting panels 12. The drive circuits 43 are provided for the respective white light-emitting panels 11, and three drive circuits 44R, 44G, and 44B are provided for each full-color light-emitting panel 12.

The drive circuits 43, 44R, 44G, and 44B each have a power transistor, not shown, and supply driving current between an anode 21 and a cathode 26 of each of the light-emitting panels 11 and 12 using the output voltage from the AC-DC converter 42. Specifically, in the drive circuits 43 for the white light-emitting panels 11, the anode 21 common in the light-emitting regions of the white light-emitting panels 11 receives an output voltage from the AC-DC converter 42; and the cathode 26 common in the light-emitting regions is connected with the power transistor, whereby the driving current is controllably supplied to all the light-emitting regions of RGB. The drive circuits 43 are provided in the plurality of white light-emitting panels 11, respectively, to drive the white light-emitting panels 11 individually. One drive circuit 43 may drive all the white light-emitting panels 11.

Meanwhile, in the drive circuits 44R, 44G, and 44B for the full-color light-emitting panels 12, the anode 21 common in the light-emitting regions of the full-color light-emitting panels 12 receives an output voltage from the AC-DC converter 42; and the cathodes 26(R), 26(G), and 26(B) are connected with the power transistors of the corresponding drive circuits 44R, 44G, and 44B, whereby the driving current is controllably supplied to each of RGB. The RGB of the full-color light-emitting panel 12 corresponds to the red light-emitting element 12R, the green light-emitting element 12G, and the blue light-emitting element 12B. The drive circuits 44R, 44G, and 44B as many as the plurality of full-color light-emitting panels 12 are provided to drive the plurality of color light-emitting panels 12 individually.

The drive control system 40 further includes a memory 45, a control circuit 46, and an operation unit 47. The memory 45 stores in advance the control data on the light emission pattern of the organic EL panel block 13 including the light-emitting panels 11 and 12. The control data refer to the driving current values of the white light-emitting panels 11 and the driving current values for each RGB of the full-color light-emitting panels 12. The control circuit 46 can control the driving action of each of the drive circuits 43 and 44 on the basis of the control data stored in the memory 45 or according to the operating conditions of the operation unit 47. The operation unit 47 can accept user's operation and can designate the light emission pattern of the organic EL panel block 13.

Although no power supply is illustrated for the memory 45, the control circuit 46, and the operation unit 47 in the drive control system 40, these units receive power from the output of the AC-DC converter 42. The drive control system 40 includes a storage battery 48, a switch 49, and a power failure detecting circuit 50 for power failure in the AC power supply 39. The power failure detecting circuit 50 detects power failure according to the presence or absence of the input voltage (or output voltage) into/from the AC-DC converter 42. The switch 49 is a power switching circuit which is turned on to apply the positive voltage from the storage battery 48 to the output line of the AC-DC converter 42 when the power failure detecting circuit 50 detects power failure. The power failure detecting circuit 50 notifies the control circuit 46 of power failure occurrence information when the power is out. The control circuit 46 switches the operation mode from the non-power failure mode to the power failure mode according to the power failure occurrence information.

When the storage battery 48 is rechargeable, the storage battery 48 may be charged with the output voltage from the AC-DC converter 42 during no power failure. In addition, the control circuit 46 and the power failure detecting circuit 50 may always operate with the storage battery 48 as a power supply.

When the control circuit 46 directs the drive circuits 43 and 44 each to work, the drive circuits 43 supply driving current between the anode 21 and the cathode 26 in the white light-emitting panels 11 and the drive circuits 44 supply driving current between the anode 21 and cathode 26 in the full-color light-emitting panels 12. The driving action of the drive control system causes the same level of light emission in the light-emitting layers 24(R), 24(G), and 24(B) of RGB to generate white light emission in the white light-emitting panels 11. On the other hand, in the full-color light-emitting panel 12, the light-emitting layers 24(R), 24(G), and 24(B) of RGB emit lights at different levels corresponding to the driving current values, and these lights are mixed to obtain emission color.

The correlation between the white light-emitting panels 11 and the full-color light-emitting panels 12 is obtained before shipment and the correction data is stored in the memory, whereby no unevenness in white light emission occurs between the white light-emitting panels 11 and the full-color panels 12 during emission of white light.

The operation unit 47, for example, as illustrated in FIG. 5, includes a power button 51 for turning the above power switch 41 on/off, as well as knobs (adjusting levers) 52 to 55 of white, R (red), G (green), and B (blue), wherein these knobs may be controlled by a user. When the knobs 52 to 55 are moved into the maximum, the control circuit 46 then directs the drive circuits 43 and 44 to perform the maximum drive. The drive circuits 43 supply driving current between the anode 21 and the cathode 26 in the white light-emitting panels 11, whereas the drive circuits 44 supply driving current between the anode 21 and cathode 26 in the full-color light-emitting panels 12. When the maximum drive is directed, the driving currents from both the drive circuits 43 and 44 become the maximum value.

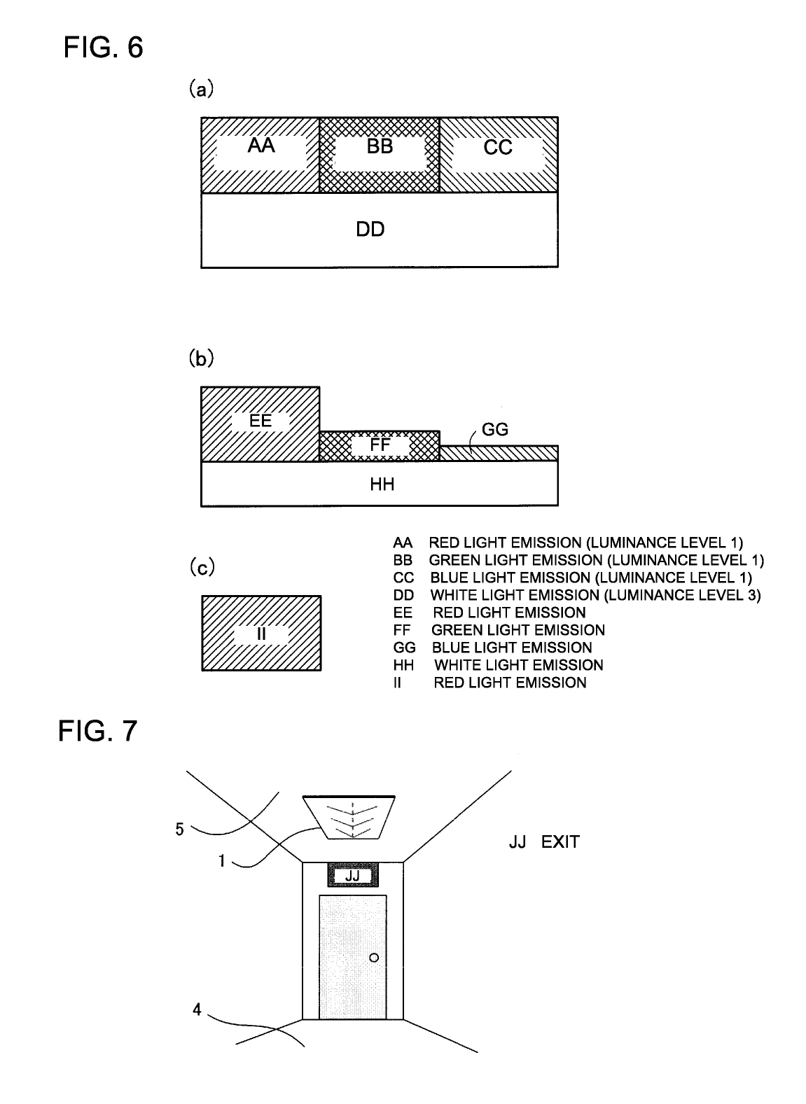

FIG. 6(a) illustrates the area ratio of the luminance level of white light emission of the white light-emitting panel 11 to the luminance levels of RGB of the full-color light-emitting panel 12 while the maximum drive is directed. When the maximum luminance level of each RGB of the full-color light-emitting panel 12 is set to 1, the white luminance level obtained by mixing the luminances of RGB is 3. The maximum luminance level of the white light-emitting panel 11 is 3. Therefore, while the maximum drive is directed, white light is emitted at a luminance level of 6.

When the surface light-emitting device of this embodiment is used as a lighting device, light is usually emitted with the parameters before the shipment. According to user's preference, the knobs 52 to 54 in the operation unit 47 can be controlled so as to obtain white light emission such that each RGB of the full-color light-emitting panel 12 has the same luminance level. At the same time, the total luminance level of white light emission can also be adjusted by controlling the knob 55.

FIG. 6 (b) illustrates the area ratio of the luminance level of white light emission of the white light-emitting panel 11 to the luminance levels of RGB of the full-color light-emitting panel 12 when red-enhanced light emission is obtained at a moderate luminance level by controlling the knobs 53 to 55. FIG. 6 (c) illustrates the area ratio of the luminance level (0) of white light emission of the white light-emitting panel 11 to the luminance levels (1 for R, 0 for G, 0 for B) of RGB of the full-color light-emitting panel 12 when only red light emission is obtained at a low luminance level by further controlling the knobs 53 to 55. Lighting by these operations is effective when requiring the coloring effect for white color lighting. The luminance level of white light emission of the white light-emitting panel 11 is first adjusted by controlling the knob 55, and thereafter coloring can be finely adjusted by controlling the knobs 52 to 54.

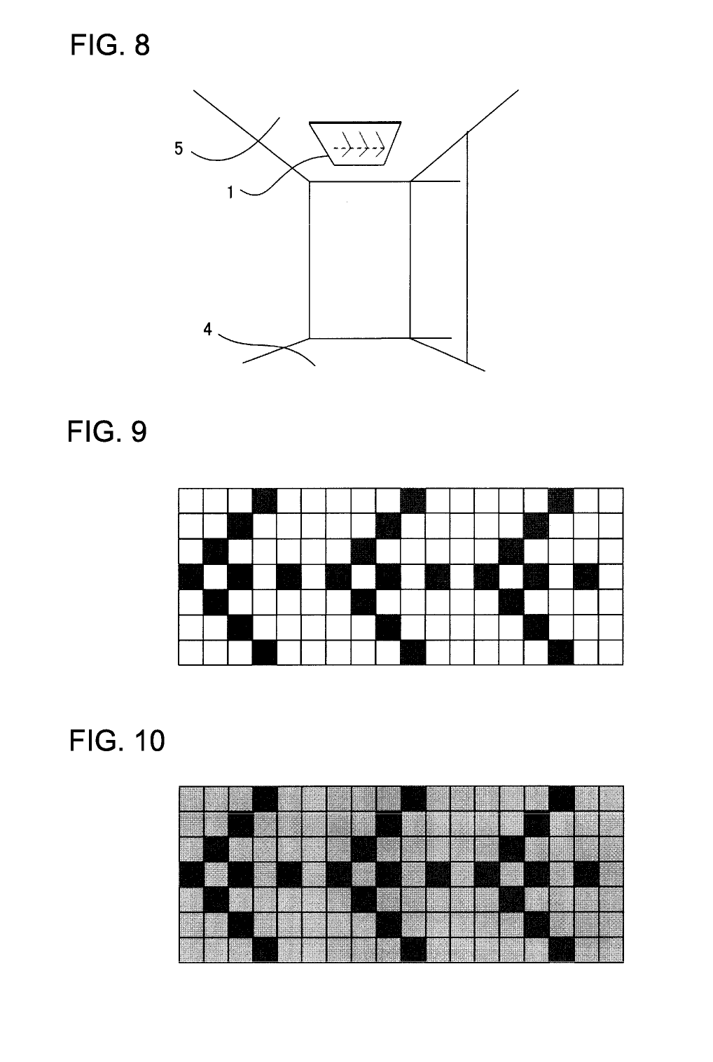

As the surface light-emitting device 1 of this embodiment is illustrated in FIGS. 7 and 8, the device can be used as an emergency evacuation light when being used by fixing it to a ceiling 5 as lighting in a hallway 4 in buildings such as hotels. When the control circuit 46 receives fire information from the outside as signals or by the input through a fire button, not shown, in the operation unit 47, the control circuit 46 reads the control data corresponding to fire in the non-power failure mode from the memory 45 to control the driving action of the drive circuits 43 and 44 on the basis of the read control data. Driving the drive circuits 43 and 44 according to this control in the non-power failure mode allows the organic EL panel block 13 to display, for example, the evacuation directional sign (meaningful two-dimensional sign) in case of fire as illustrated in FIG. 7. In FIG. 9, the arrow portions are lighted in red and the other portion is displayed in white color. The full-color light-emitting panels 12 are used in the arrow portions for the evacuation directional sign, and the white light-emitting panels 11 and the full-color light-emitting panels 12 corresponding to the other portion than the arrow portions generate white light emission. The direction of the arrows of the evacuation directional sign can be arbitrarily set according to the control data.

When receiving the power failure occurrence information described above from an automatic switching circuit 49 in such an emergency, the control circuit 46 becomes power failure mode and reads from the memory 45 the control data corresponding to fire in the power failure mode to control the driving action of the drive circuits 43 and 44 on the basis of the read control data. Driving the drive circuits 43 and 44 according to this control in the power failure mode allows the organic EL panel block 13 to display, for example, the evacuation directional sign in case of fire in the power failure mode as illustrated in FIG. 10. In FIG. 10, the arrow portions are displayed in red color and the other portion is displayed in dark color or is lighted off. That is, the luminance of the other portion than the arrow portions in the meaningful two-dimensional display decreases.

The color of the evacuation light may change with the situations such as abnormal smell and earthquake, in addition to fire, in case of emergency. For example, in case of abnormal smell, the arrow portions are lighted in orange color and the other portion is displayed in white color in the non-power failure mode, whereas the arrow portions are displayed in orange color and the portion part is lighted off in the power failure mode. In case of earthquake, the arrow portions are displayed in red color and the other portion is displayed in white color in the non-power failure mode, whereas the arrow portions are displayed in blinking red color and the other portion is lighted off in the power failure mode. In other cases, the arrow portions are lighted in blue color and the other portion is displayed in white color in the non-power failure mode, whereas the arrow portions are displayed in blinking blue color and the other portion is lighted off in the power failure mode. In the power failure mode, the light-emitting panels to be lighted on in the organic EL panel block 13 are limited to the portions required for displaying the evacuation light, thereby reducing power consumption.

The surface light-emitting device of the embodiment has the light-emitting surface including the white light-emitting panels 11, which are single-color light-emitting panels, and the full-color light-emitting panels 12, which are multi-color light-emitting panels. This configuration excludes extremely special single-color light emission on the entire surface, such as red light emission on the entire surface, which are rare light emission conditions in ordinary use. Therefore, this surface light-emitting device not only can function as lighting but also can form complex expressions such as evacuation directional signs without any practical problem as compared with surface light-emitting devices having all full-color light-emitting panels. The full-color light-emitting panels 12 need to be driven for each RGB, but the white light-emitting panels 11 only need to be driven as a unit of the white light-emitting panels 11 or all the white light-emitting panels 11 only need to be collectively driven. Therefore, the drive circuits 43 for the white light-emitting panels 11 may only have a simpler configuration than the drive circuits 44 for the full-color light-emitting panels 12, which can reduce cost with the surface light-emitting device of the embodiment as compared with surface light-emitting devices using all full-color light-emitting panels.

The use of OLEDs, such as organic EL elements, as single-color light-emitting panels and multi-color light-emitting panels like in the embodiment enables light emission having wide spectrum. In particular, the combination of RGB can form multicolor with colors of fine tone.

In the surface light-emitting device of the embodiment as described above, the plurality of white light-emitting panels 11 and the plurality of full-color light-emitting panels 12 are formed on the common glass substrate 10, but the white light-emitting panels 11 and the full-color light-emitting panels 12 may be formed on different substrates.

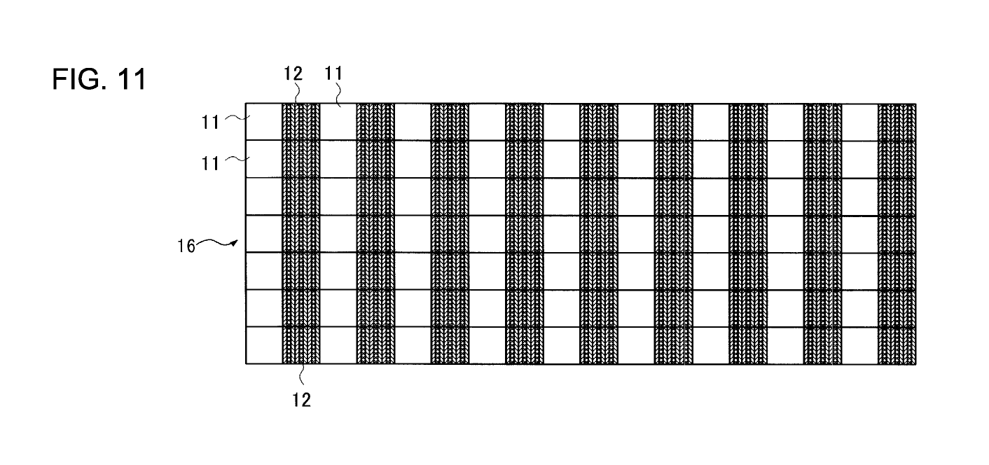

FIGS. 11 to 14 illustrate the light-emitting surfaces of surface light-emitting devices as other embodiments of the present invention. In an organic EL panel 16 of the surface light-emitting device in FIG. 11, a stripe pattern is formed as a predetermined pattern. White light-emitting panels 11, which form the white areas, and full-color light-emitting panels 12, which form the multi-color areas, are alternately disposed in one direction (longitudinal direction), while a plurality of identical light-emitting panels (the white light-emitting panels 11, the full-color light-emitting panels 12) is continuously disposed in the direction perpendicular to the one direction (traverse direction).

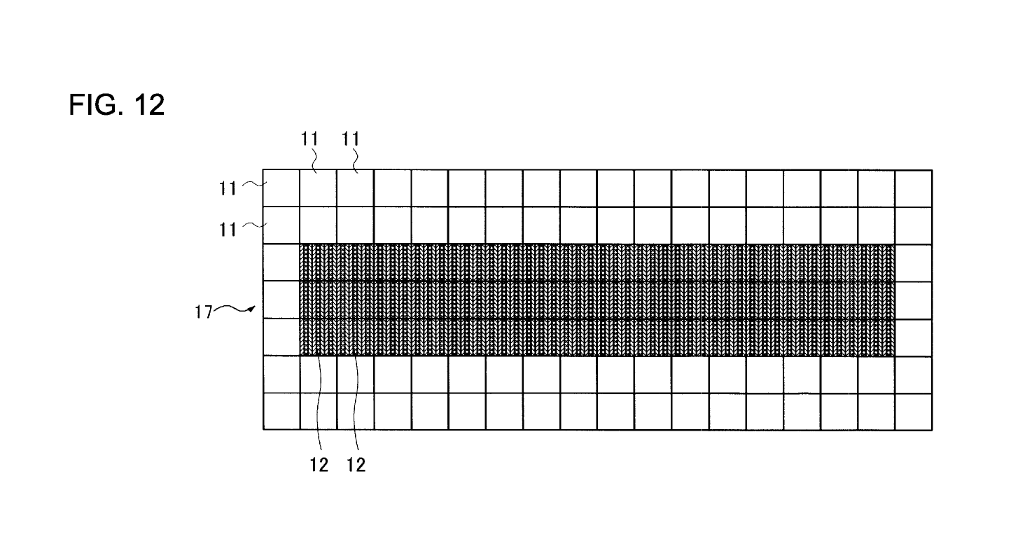

In an organic EL panel 17 of the surface light-emitting device of FIG. 12, a plurality of full-color light-emitting panels 12, which forms the multi-color area, is disposed at the center of the light-emitting surface as a group of the rectangular shape of 3×16 panels, while a plurality of white light-emitting panels 11, which forms the white area, is disposed around the plurality of full-color light-emitting panels 12.

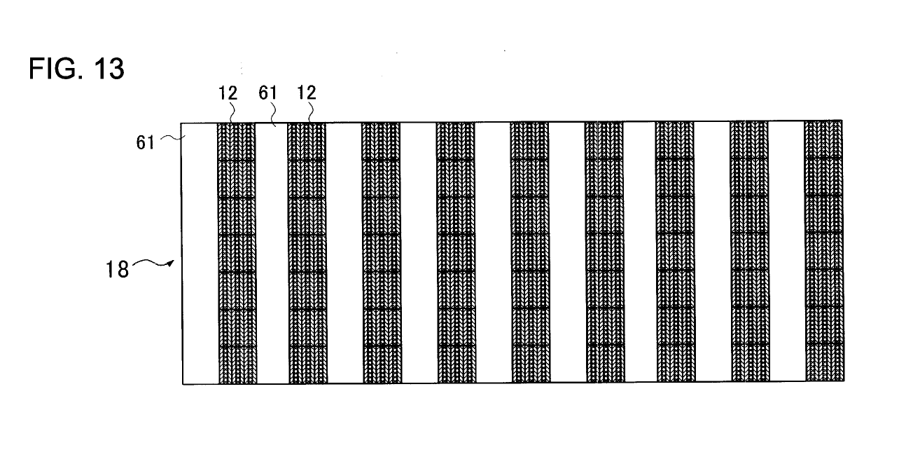

In an organic EL panel 18 of the surface light-emitting device of FIG. 13, long white light-emitting panels 61 are used as panels forming the white areas. Seven full-color light-emitting panels 12 are arranged along the same length as the longitudinal direction of the white light-emitting panel 61, while the white light-emitting panels 61 and the seven full-color light-emitting panels 12 are alternately disposed in the direction perpendicular to the longitudinal direction. This forms a light-emitting surface similar to the surface light-emitting device of FIG. 11.

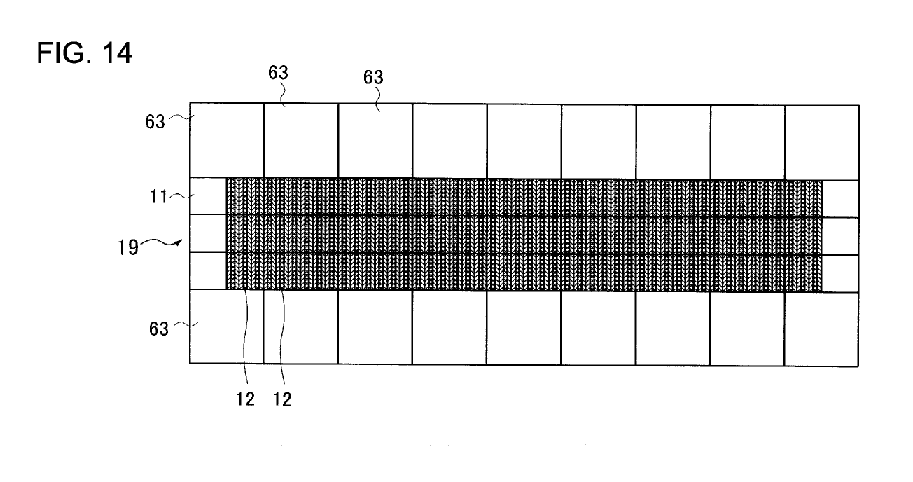

In an organic EL panel 19 of the surface light-emitting device of FIG. 14, white light-emitting panels 63 which are 4 times larger in size than the above white light-emitting panels 11 are used as single-color light-emitting panels to from a light-emitting surface similar to the surface light-emitting device in FIG. 12.

The surface light-emitting devices having the organic EL panels of FIGS. 11 to 14 enable complex expressions with the drive control system having a relatively simple configuration similar to the surface light-emitting device of FIG. 1.

The above embodiments describe the surface light-emitting devices having organic EL elements in the light-emitting regions of the light-emitting panels 11, 12, 61, and 63, but the present invention may be a surface light-emitting device having light-emitting elements, such as LED (light-emitting diode), other than organic EL elements in the light-emitting regions of the single-color light-emitting panels and the multi-color light-emitting panels. A light diffusion layer may be provided on the light-emitting elements.

The light-emitting regions of the white light-emitting panels 11 and the full-color light-emitting panels 12 are arranged at regular intervals in the above embodiments. The present invention, however, is not limited to these and, for example, the intervals may be a combination of wide intervals and narrow intervals. The light-emitting regions are not limited to straight and may be curved.

The above embodiments describe the surface light-emitting devices having the full-color light-emitting panels, but the multi-color light-emitting panels in the present invention are not limited to the full-color light-emitting panels as long as the panels can emit a plurality of colors. The single-color light-emitting panels are not limited to the white light-emitting panels and may be light-emitting panels that emit single color, such as daylight color other than white color, day white color, warm white color, and electric bulb color.

The above embodiments describe, as light-emitting panels, bottom emission type organic EL panels which emit light from a bottom substrate such as the glass substrate 10 as illustrated in FIGS. 2 and 3. In the present invention, however, top emission type organic EL panels may be used which emit light from the sealing member side.

The surface light-emitting device of the present invention can be used for organic EL lighting devices, lighting devices with an information display function, evacuation assistance devices, illumination devices, and message boards.

### REFERENCE SIGNS LIST

10 glass substrate
13, 16-19 organic EL panel block
11, 61, 63 white light-emitting panel
12, 62 full-color light-emitting panel
21 transparent electrode
22 bank
23 hole injection layer
24(R), 24(G), 24(B) light-emitting layer
25 electron injection layer
26, 26(R), 26(G), 26(B) metal electrode
40 drive control system

1. A surface light-emitting device comprising a light-emitting surface including a single-color area and a multi-color area disposed alongside the single-color area, wherein the single-color area comprises a plurality of single-color light-emitting panels, and the multi-color area comprises a plurality of multi-color light-emitting panels.

2. The surface light-emitting device according to claim 1, wherein the multi-color area has a predetermined pattern.

3. The surface light-emitting device according to claim 2, wherein the predetermined pattern is a checkered pattern.

4. The surface light-emitting device according to claim 2, wherein the predetermined pattern is a stripe pattern.

5. The surface light-emitting device according to claim 2, wherein the predetermined pattern is a rectangular pattern positioned at a center of the light-emitting surface.

6. The surface light-emitting device according to claim 1, wherein the single-color light-emitting panels and the multi-color light-emitting panels have an identical shape.

7. The surface light-emitting device according to claim 6, wherein the single-color light-emitting panels and the multi-color light-emitting panels have a rectangular shape.

8. The surface light-emitting device according to claim 1, wherein the single-color light-emitting panel includes a panel that is integral multiples of a size of the multi-color light-emitting panel.

9. The surface light-emitting device according to claim 2, further comprising a drive control system including a first drive circuit that drives the single-color light-emitting panel and a second drive circuit that drives the multi-color light-emitting panel.

10. The surface light-emitting device according to claim 9, wherein the multi-color light-emitting panels have light-emitting elements of RGB (red, green, blue), and the second drive circuit includes three drive circuits that drive the light-emitting elements of RGB, respectively.

11. The surface light-emitting device according to claim 10, wherein the drive control system further comprises a control circuit that individually controls the first drive circuit and the three drive circuits in the second drive circuit according to control data or input operation.

12. The surface light-emitting device according to claim 11, wherein the control circuit allows the light-emitting surface to generate two-dimensional signs through the first drive circuit and the three drive circuits in the second drive circuit according to the control data.

13. The surface light-emitting device according to claim 12, wherein the drive control system further comprises:
a converter that converts an output voltage from an AC power supply into a direct voltage to provide a driving power supply for the single-color light-emitting panels and the multi-color light-emitting panels through the first drive circuit and the second drive circuit;
a power failure detecting circuit that detects power failure in the AC power supply; and
a power switching circuit that uses a storage battery as a driving power supply when the power failure detecting circuit detects power failure in the AC power supply.

14. The surface light-emitting device according to claim 13, wherein the control circuit controls the first drive circuit and the three drive circuits in the second drive circuit to decrease other luminances than the two-dimensional sign in the light-emitting surface when the power failure detecting circuit detects power failure in the AC power supply.

15. The surface light-emitting device according to any claim 2, wherein light-emitting elements in the single-color light-emitting panels and light-emitting elements in the RGB comprise organic EL elements.

16. The surface light-emitting device according to claim 15, wherein the single-color area is a white area, and the single-color light-emitting panel is a white light-emitting panel.

17. The surface light-emitting device according to claim 16, wherein the control circuit obtains data from a memory storing in advance a correlation between the single-color light-emitting panels and the multi-color light-emitting panels during single-color light emission to control both panels not to generate various kinds of spots during single-color light emission.

18. A surface light-emitting device comprising:
a light-emitting surface including a single-color area and a multi-color area disposed alongside the single-color area, wherein
the single-color area is formed by a plurality of single-color light-emitting panels and the multi-color area is formed by a plurality of multi-color light-emitting panels, and
the plurality of multi-color light-emitting panels are configured to display a blinking pattern.

19. The surface light-emitting device according to claim 18, wherein
the light-emitting surface is a curved surface.

20. The surface light-emitting device according to claim 18, wherein
the plurality of single-color light-emitting panels has a greater area than an area of the plurality of multi-color light-emitting panels.

21. A light-emitting device comprising:
at least one single-color light-emitting panel; and
at least one multi-color light-emitting panel,
wherein the at least one multi-color light-emitting panel is configured to change colors in a pattern.

22. The light-emitting device of claim 21, wherein the at least one multi-color light-emitting panel is disposed adjacent to the at least one single-color light-emitting panel.

23. The light-emitting device of claim 21, wherein the changing colors comprises lighting and unlighting one color of the at least one multi-color light-emitting panel in the pattern.

24. The light-emitting device of claim 21, wherein the at least one single-color light-emitting panel comprises a plurality of single-color light-emitting panels configured to form a single-color area; and
the at least one multi-color light-emitting panel comprises a plurality of multi-color light-emitting panels configured to form a multi-color area.

25. The light-emitting device of claim 24, wherein the multi-color area is disposed adjacent to the single-color area.

26. The light-emitting device of claim 24, wherein each of the plurality of multi-color light-emitting panels is configured to change colors in a pattern.

27. The light-emitting device of claim 26, wherein the pattern comprises lighting and unlighting one color each of the plurality of multi-color light-emitting panel in the pattern.

28. The light-emitting device of claim 26, wherein a pattern of any of the plurality of multi-color light-emitting panels is different than a pattern of others of the plurality of multi-color light-emitting panels.
